(19) United States
(12) Patent Application Publication
(10) Pub. No.: US 2016/0353578 A1
(43) Pub. Date: Dec. 1, 2016

(54) Printing Method for Fabrication of Printed Electronics

(71) Applicant: Jun Yang, London (CA)

(72) Inventors: Jun Yang, London (CA); Xiaolong Wang, London (CA); Tengyuan Zhang, London (CA); Qiuquan Guo, London (CA)

(21) Appl. No.: 14/552,479

(22) Filed: Nov. 24, 2014

Related U.S. Application Data
(60) Provisional application No. 61/908,798, filed on Nov. 26, 2013.

(51) Int. Cl. H05K 3/12; H05K 3/18

(52) U.S. Cl. CPC H05K 3/125; H05K 3/181; H05K 2203/1163; H05K 2203/1157

(57) ABSTRACT

This invention relates to fabrication of high quality printed electronics, particularly without the use of conductive inks, on various substrates by printing catalyst based inks followed by electroless deposition of metals. A method comprising substrate surface modification, preparing catalyst based inks, electroless deposition of a thick layer of metal and post-printing treatment is disclosed.

### BACKGROUND

Printed flexible electronics and devices which can maintain functionality when subject to a large deformation and stress have broad applications. The conductivity, the resolution and the cost are of great concerns for manufacturing. There is an increasing demand for high quality and low cost electronic components such as RFID tags, super capacitor, flexible sensor and devices, which require innovative fabrication techniques that are faster but cheaper compared to traditional production methods. It is predicted that the market of flexible organic and printed electronics will exceed $300 billion by 2028.[1] Conventional fabrication methods for electronics are mostly based on lithography technique, a complex and time-consuming process that involves expensive facilities and large volumes of hazardous waste. The emerging nanotechnology is also evolved in fabricating electronics such as solar cell and super capacitor, however, its high cost and requirement for high-end facilities limit its appeal. In this regard, printing techniques, such as inkjet printing, flexographic printing, laser printing, and screen printing, and coating techniques, such as spray coating and non-vacuum deposition, have emerged as promising technical trends to produce flexible electronics and devices.[2-8]

WO2011019523 A3 disclosed a method based on roll mechanics and conductive inks for making printed electronics, WO2014021941 A1 and US20030151028 A1 disclosed a method of synthesizing conductive inks and demonstrated the fabrication of printed electronics using the flexographic and gravure techniques. In U.S. Pat. No. 8,697,485 B2, a conductive graphene ink was printed electrohydrodynamically onto glass substrate based on the method disclosed in WO 2007/053621. The mask based screen printing technique was also adopted to print functional multilayer structure, and was demonstrated in U.S. Pat. No. 6,573,023 B2. Inkjet printing, which is widely used in home and office, has also been employed extensively as a low cost tool to explore various aspects of printed electronics in a laboratory setting, such as ITO free polymer solar cell, functional polymer films, complex heterogeneous tissue constructs and thin film transistors. For printed electronics, most of the research efforts are focused on direct printing of metal nanoparticles or conductive polymer, followed by thermal or other treatment to make them conductive. For example, as is disclosed in U.S. Pat. No. 8,810,996 B2, graphene oxide conductive ink was deposited onto the substrate using inkjet method, and in US20140302292 A1 nanoparticles were deposited by inkjet printing to form functional devices. Although the resolution of the final resulted metal pattern has been improved, clogging is always a common critical issue for micron size nozzles due to the accumulation of nanoparticles at the nozzle opening. In addition, other than the high cost of Ag-nanoparticles, more critical issues reside in the oxidization and sedimentation stability of the corresponding inks, which generally requires a large amount of stabling and decoration agent and a very low concentration of metal particles. All of these will consequently lead to a high resistance of the printed patterns. Thus it is desirable to find an efficient and low cost way to obtain high quality electronic circuits, especially with thick metal to achieve high conductivity.

### SUMMARY

In one aspect, this invention develops a new concept of making high quality printed electronics. Instead of printing conductive inks, the catalyst based ink was printed followed by electroless deposition (ELD) to enable electronic circuits with thick metal on various substrates. The method comprises:
(i) modifying substrates with functional groups for catalyst capturing and immobilization;
(ii) printing catalyst based inks on desired substrates, such as paper, plastic, aluminum oxide, glass, silicon, metals and textiles;
(iii) electroless deposition of metals to make sufficiently thick metal layer; and
(iv) post-printing treatment like thermal sintering, inductive sintering or photonic sintering.

The modification of step (i) is carried out by surface initiated polymerization of acrylate or methacrylate monomer, or self-assembly of polyelectrolytes to introduce functional groups for catalyst immobilization during printing. A post-application process like cross-linking or curing may be applied to improve the adhesion.

In another aspect, this invention develops catalyst based inks for printing electronics circuit on various substrates. The catalyst based ink may be in the form of liquid, gel, aerosol, paste, solid or powder. The formed catalyst based ink can be applied on substrate by both printing techniques, including inkjet printing, screen printing, laser printing, gravure printing and flexographic printing, and other deposition methods, including spray coating, non-vacuum deposition, micro-contact printing and etc. The catalyst based ink can be formed with various noble metals, such as Pd, Pt, Au or Ag, by either dissolving In a liquid solvent like a mixture of water and glycerol to form solution or gel with appropriate viscosity and surface tension, or mixing with a solid solvent like toner to formulate a powder form of ink. Overall, the catalyst based ink can be prepared in different forms to be suitable for various applications with the choice of the substrate and the printing technique.

In another aspect, this invention provides a solvent-free approach to fabricate high quality flexible electronics by printing a modified toner. Only two steps are involved in the procedure: printing designed pattern with solid catalyst based ink and ELD of copper. The key to this solvent free printing method is the fabrication of a functional toner additive which is compatible with the regular laser printer, does not affect the electric charge properties of the original toner, has a strong adhesion with the printed toner, and does not dissolve or migrate away from the printed pattern during the ELD process.

In yet another aspect, this invention provides an ELD method to fabricate electronics circuit with a thick layer of metal. The method includes the steps of: (a) printing desired features on a substrate with prepared catalyst; (b) conducting ELD process to plate desired metal with sufficient thickness on the printed feature; and (c) post-printing treatment to improve the quality of obtained circuit. The printing can be performed with desktop Inkjet printer, commercial material printer, laser printer or other printing/deposition methods mentioned. Particularly, for inkjet printing, pure catalyst noble-metal-containing salt solution without using any kind of particles can overcome the issue of nozzle blocking and enables greater printing resolution. And for solvent free laser printing, noble-metal-containing salt was mixed with thermoplastic polymer enabling functional high resolution laser printing, and making high performance thick copper feature to realize high quality electronics circuit.

The ELD is conducted by immersing into a plating bath for 1-120 min, wherein the plating bath can be Cu plating, Ni plating and Silver plating. The Cu plating bath contains a 1:1 mixture of freshly prepared solutions A and 8. Solution A contains 12 g/L NaOH, 13 g/L CuSO₄.5H₂O and 29 g/L potassium sodium tartrate and Solution B contains 9.5 mL/L HCHO in water. The Ni plating bath contains 40 g/L Ni₂SO₄.5H₂O, 20 g/L sodium citrate, 10 g/L lactic acid, and 1 g/L dimethylamine borane (DMAB) in water. A nickel stock solution of all components except the DMAB was prepared in advance. A DMAB aqueous solution was prepared separately. The stock solutions were prepared for a 4:1 volumetric proportion of nickel-to-reductant stocks in the final electroless bath. The silver plating bath contains 1:1 mixture of freshly prepared 5 g/L of potassium sodium tartrate solution and solution containing 1 g/L AgNO₃ and a small amount of ammonia water.

The post-printing treatment mainly comprises a sintering process to improve conductivity of the metal patterns by ELD and lamination process. Thermal sintering, inductive sintering or photonic sintering by high-power pulsed light may be used for the sintering purpose.

Additional aspects of the invention will be set forth further in the following context, including figures, the detailed description, and any claims, or can be learned by practice of the invention. It is to be understood that both the foregoing general description and the following detailed description are exemplary and explanatory only and are not restrictive of the invention as disclosed.

### BRIEF DESCRIPTION OF THE DRAWINGS

FIG. 1 is a schematic illustration of paper-based metal patterns with high resolution and conductivity via printing catalyst based ink and subsequent ELD process.

FIG. 2 (a) shows UV/visible-spectra (fitted) of freshly prepared palladium (II) salt ink (triangle facing down) and inks after storage at room temperature for 8 hours (triangle facing up), 3 days (round circle), 180 days (square) and 180 days stored under 4° C. (diamond), and images of prepared inks from one day to 180 days; (b) catalyst based ink prepared with toner.

FIG. 3 shows: (a) Misdirected jetting caused by accumulated leaked ink around the nozzle. (b) Satellite droplets caused by relative high jetting voltage. (c) Droplets after applying the optimum parameters (meniscus vacuum: 3.5 H₂O, jetting voltage peak 24.30 V, single jetting duration: 32.192 μs (phase 1: 9.792 μs, phase 2: 6.160 μs, phase 3: 8.496 μs, phase 4: 5.184 μs), maximum jetting frequency: 20 kHz).

FIG. 4 shows Modified waveform for the ammonium etrachloropalladate (II) ink:

FIG. 5 shows scanning electron microscopy (SEM) image of the cross section of the ELD copper layer.

FIG. 6 shows: (a) Microscope images of the final copper patterns of high resolution (left) and inductive micro-coil (right); (b) Flexible Functional circuit board (left), integrated circuits with RFID antenna (right).

FIG. 7 is the conductivity comparison of sintered, un-sintered, bent (inward and outward, radius of curvature: 1 cm⁻¹), un-bent, stored 3 hours under 120° C., stored 180 days under room temperature and bulk copper lines.

FIG. 8 shows: (a) SEM images of the deposited copper before sintering and (b) after one hour thermal sintering under nitrogen flow; (c) atomic force microscopy (AFM) 3D morphology of copper layer before sintering and (d) after one hour thermal sintering.

FIG. 9 (a) AFM images showing the roughness of copper (before sintering) on photopaper after ELD bath and photopaper before ELD; (b) AFM Section profiles of selected parts showing in (a) with white dash lines, corresponding to the copper, photopaper after ELD and photopaper before ELD respectively. (c) XRD patterns of photopaper, copper on photopaper after sintering and copper on photopaper before sintering.

FIG. 10 Electronics pattern prepared by screen printing method

FIG. 11 Electronics circuit prepared with silver nitrite as catalyst by inkjet printing

FIG. 12 (a) SEM image of the copper surface prepared by laser printing; (b) a typical cross section of thick copper on the treated substrate

FIG. 13 (a) Electronics circuit prepared by laser printing method and (b) a functional circuit with LED flashing controlled by electronic components

FIG. 14 Double layer flexible LED display prepared by laser printing catalyst based ink

### DETAILED DESCRIPTION

As used herein, the “catalyst ink” encompasses materials that may include noble metal salts, solvent and polymers. Examples of polymers include polyesters, polyimides, polyamide, ABS, polylactide (PLA) etc. The catalyst ink may be in the form of liquid, gel, aerosol, paste, solid or powder. The catalyst ink may be applied to the substrate using any suitable coating or printing technique. The candidate coating or printing techniques include, but not limited to, spray coating, spin coating, inkjet printing, screen printing, laser printing, flexographic printing, microcontact printing, xerography etc. The substrate may be any suitable materials such as paper, polymers, glass, silicon, metals, wood, and textile, and so on.

In this invention, a convenient and low-cost method for printed electronics has been developed that involves a process of printing catalysts and a following ELD process, and post-printing treatment to prepare high-resolution and high-conductivity metal patterns. ELD is an auto-catalytic technique used to deposit metals (copper, nickle, etc.) on various substrates such as paper, plastic, aluminum oxide, glass, silicon, metals and textiles. The mechanism of ELD has been well studied these years, making it a convincing technique for making metal coating and patterns. Abundant metal ions in the ELD bath can create patterns with dense surface, which in turn results in good conductivity close to bulk materials.

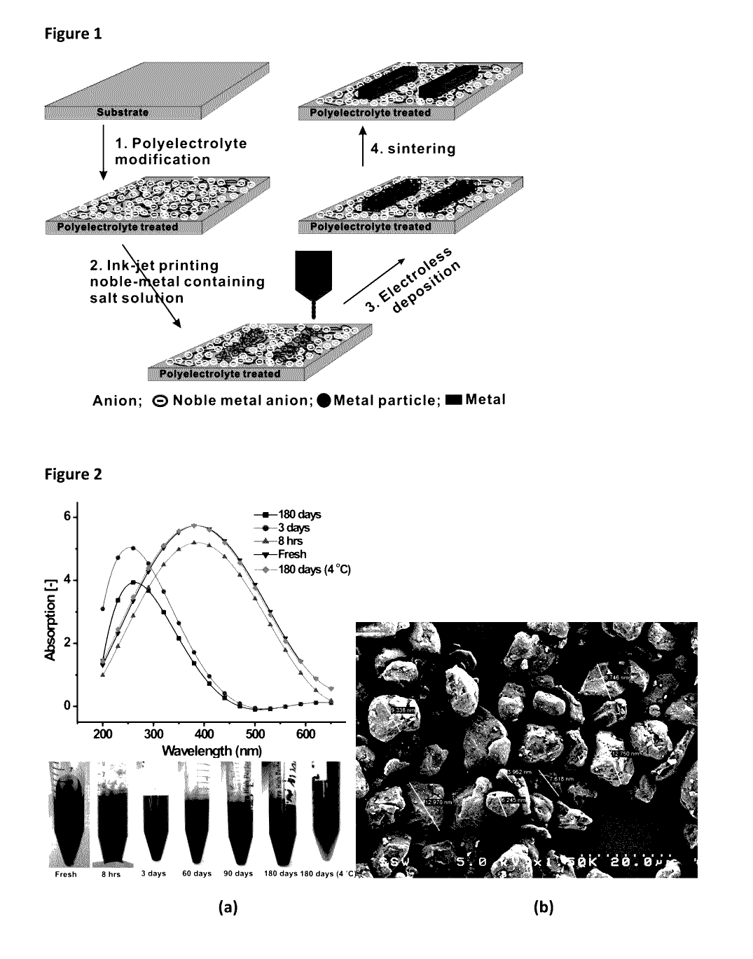

For example, as shown in the scheme of FIG. 1, metal patterns were fabricated on flexible substrates by inkjet printing.

The substrates used for printing were first modified by polyelectrolyte by surface initiated atom transfer radical polymerization.

A glycerol-water solution with viscosity of ˜11 centipoise (cp) was achieved by mixing anhydrous glycerol and distilled water in the ratio 3:2 by volume. Noble metal salt was dissolved in the mixture to form a solution with viscosity of 10-12 cp at room temperature. The noble metal solution was then ink jet printed on the polyelectrolyte modified substrate.

Electroless deposition process was conducted to apply copper pattern onto the printed feature by immersing into the freshly prepared plating bath for different time to achieve desired thickness, particularly, large thickness of metal layer can be obtained using this method.

### EXAMPLES

The invention can be further understood by the skilled person with reference to the following examples, which are exemplary, and the inventors' technology is not limited in scope by the exemplified embodiments. Various modifications of the present technology in addition to those described herein will become apparent to those skilled in the art from this description and accompanying figures.

### Examples 1

Modification of substrate. EPSON Ultra Premium Photopaper Glossy, treated with polyelectrolytes containing quaternary ammonium was selected to be substrate.

### Examples 2

Preparation of noble metal salt ink. A glycerol-water solution with viscosity of ˜11 centipoise (cp) was achieved by mixing anhydrous glycerol and distilled water in the ratio 3:2 by volume. Ammonium tetrachloropalladate (II) was then added, followed by 4 minutes mixing in the mixer until a clear dark yellow solution was obtained. The optimum viscosity for inkjetable fluids in piezoelectric Drop-on-Demand (DOD) printhead reported in literature is 10-12 cp at room temperature. Based on these, inkjet printable inks containing different concentration of palladium ions were prepared and viscosity was measured. To find the optimum ink for the following inkjet printing and ELD process, solutions with different Pd salt concentration (10-60 mM) were prepared in the same way. All prepared inks were degassed under a vacuum chamber of 2 psi for 1 hour to remove dissolved gas, followed by filtering with a 0.2 μm springe filter to get rid of undesired particles which could cause jetting clog. The final viscosity was measured with a Gilmont GV-2100 Falling Ball Viscometer to further confirm it was in a proper range.

Negatively charged tetrachloropalladate group (—PdCl₄²⁻) tends to form chemical bonds with the positively charged quaternary amine group (NR₄⁺−) on the photopaper. A bivalent tetrachloropalladate group will combine with two monovalent quaternary amine groups when the ink droplet is in contact with the photopaper substrate which results in a strong adhesion between the palladium ions and the substrate. Rate of ELD of copper as well as the plated copper density are proportional to the concentration of catalyst (palladium ion in this case), thus a high concentration of the palladium salt is preferred. However, the number of quaternary amine groups on the surface of photopaper is limited, which means excessive palladium salt will result in unbonded palladium ions on the surface. Unbonded Ions will disperse on the photopaper and dissolve in deposition solution during the process of ELD, causing serious losses in resolution. Therefore, inks with concentrations ranging from 10 mM to 60 mM were prepared to find the optimal solution. For inks stored at room temperature, visible precipitation was clearly observed 3 days later and gradually increased with time, as shown in FIG. 2. The palladium salt solutions after standing up to 180 days at 4° C. showed no precipitation or deterioration. The color of the ink is still dark yellow just as that of the initial solution. The ink remained stable under 4° C. for more than 180 days without observation of sediment and also showed its capability of producing successful printing results. Inks stored under room temperature after 30 days still showed its ability to trigger the ELD process, but the ELD process was in a very low rate, usually taking more than 3 hours to complete and the deposited patterns were no longer uniform and continuous, indicating that such inks were no longer suitable for making a high resolution functional circuits. Thus, all the inks used for final printing were either fresh made or those stored at 4° C.

### Example 3

The preparation of catalyst-containing toner (case of solid ink): As-synthesized toner and commercial laser printing toners are both available for the production of modified toner.

The catalyst ammonium tetrachloropalladate(II) [(NH4)2PdCl4] is grinded into fine powders by ball milling or other pulverization method, such as planetary ball milling, mechanical grinding. Then the grinded catalyst powders are dry blended with toner particles by mechanical method, typically including ball milling, blast mixing, and stirring mixing. Small, homogeneous, and evenly colored catalyst-containing toner is produced and collected for the characterization and use.

### Examples 4

Inkjet printing and parameters optimization. Printing patterns were designed and drew with vector drawing software with color values set to R=0, G=0, B=0 and exported as binary bmp format in bitmap color model with a resolution of 1300 ppi. Inkjet printing was performed using a commercially available inkjet Dimatix DMP-2800 materials printer (FUJIFIL Dimatix, USA), equipped with a 1 pL piezoelectric DOD 16-jet cartridge that can deposit features as small as 20 μm. Printing parameters such as jetting period, jetting voltage control waveform, meniscus vacuum, printhead temperature were dynamically adjusted according to the real-time droplets video generated by a built-in high frequency camera. Epson Ultra-Premium Glossy photopaper was used as the substrate for printing and was cut into a 10 cm×10 cm square to reduce deformation caused by heating and wetting. Prepared photopaper was placed on a vac-sorb substrate with temperature at 30° C. and fixed by scotch tape. Lines of the same width were printed with the drop space set to 20 μm, 25 μm, 30 μm and 35 μm respectively and examined by microscope. Results showed a drop space of 25 μm giving the best pattern thus complex and functional patterns were then printed with optimum settings (maximum jetting frequency 20 kHz, drop space 25 μm, meniscus vacuum 3.5 H₂O, printhead temperature 30° C., printhead angle 3.6°, jetting period 41.792 μs, jetting voltage 23.60±0.4 V, printing height 150 μm, cleaning cycle of 1 s purging—1 s spitting—2 s blotting, tickle mode on with frequency 2 kHz).

The cartridge of ink jetting devices is always operated under negative pressure to keep the meniscus at the edge of the nozzle and prevent the ink from dripping under the action of gravity. The pressure difference between the inside and outside of the cartridge, which is also known as the meniscus vacuum, needs to be adjusted depending on the viscosity and surface tension of the ink. To obtain the optimum meniscus vacuum level, a built-in camera was used to monitor the formation of droplets in real time. Meniscus vacuum level was set to 3.2, 3.3, 3.5, 3.8 and 4.0 (inches of water) and under each level the printhead continuously worked for 10 minutes. Results showed that a meniscus vacuum of 3.5 H₂O gave the most stable and reliable ejected droplets. Leakage was observed on some of the nozzles when the vacuum level was lower than 3.5 H₂O. The leaked ink attached and accumulated around the nozzle, causing misdirected jetting and blocked nozzle. For the vacuum level higher than 3.5 H₂O, a relative high voltage (˜28 V) must be applied to the nozzle in order to overcome the excessive negative pressure to make it jet. However, the Increased voltage results In the breakup of the liquid ligament which consequently leads to the generation of a primary drop and one or several satellite droplets. Typically, the satellite droplets may cause undesired patterns and a serious loss in resolution, and therefore should be avoided as much as possible. For the piezoelectric printhead, the velocity of droplet ejected from the nozzle is a function of applied voltage. We observed that the distance (from the nozzle plate to the place where droplet fully formed) traveled by the droplet also increased with the applied voltage. Higher voltage results in a bigger dot diameter because of the increased ink droplet's mass and velocity, which means a reduction in the printed resolution. By applying a meniscus vacuum of 3.5 H₂O, the optimum jetting voltage peak for the palladium ink was found to be ˜24.3 V using the same real-time monitoring method.

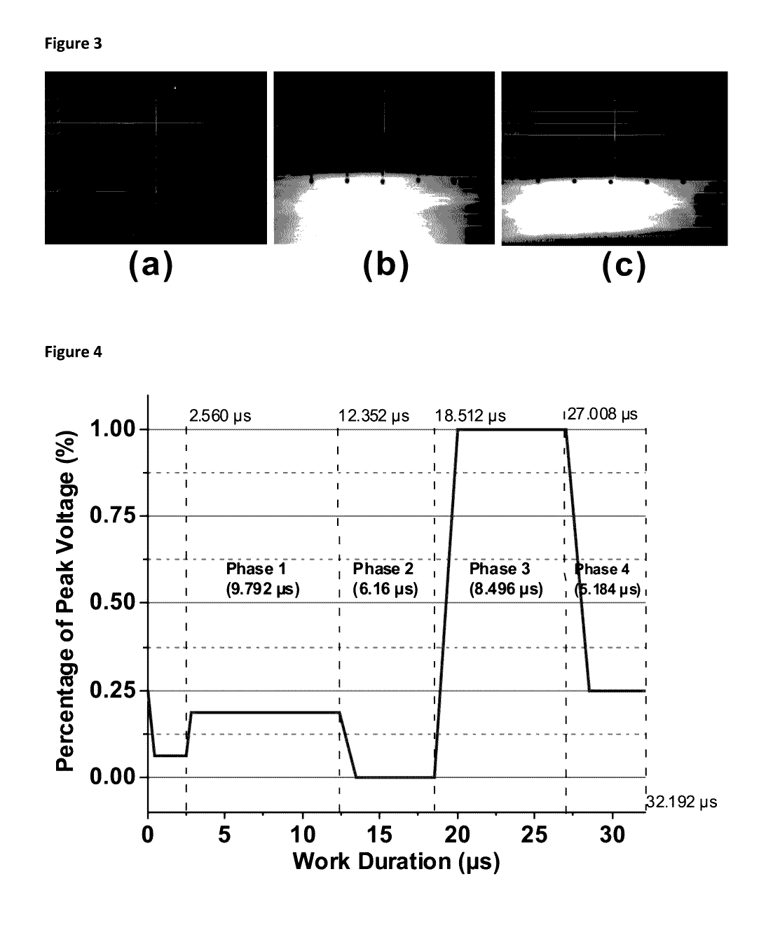

Nozzle clog was observed sometimes during real-time monitor, which was unacceptable for a high resolution printing (FIG. 3). Since all the inks were degased and filtered by a 0.2 μm syringe filter, clogging should not be caused by undesired large particles or bubbles in the ink. Thus, the great possibility may reside in the voltage waveform used for controlling the bimorph on each nozzle. The bimorph is slightly deflected so that the fluid chamber above the nozzle is depressed by a bias voltage. Typically, the voltage waveform is divided into four segments, and each segment has three properties: slew rate, duration and level. The first segment is called the loading work during which a decreased voltage is applied to the bimorph at the beginning of the jetting, bringing the bimorph back to a relaxed position with the chamber at its maximum volume. However, for the palladium salt ink the loading work segment will lead to the generation of micro-bubbles in the nozzle, prohibiting formation of droplets since the nozzle works in a high jetting frequency up to 20 kHz. Effect of such micro-bubbles is magnified in a nozzle with a diameter of only 10 micron. Thus, we reduced the decreased level of the first phase, and got the optimum jetting waveform shown in FIG. 4. A reduced level (˜50% of the initial one) of jetting voltage was applied to phase one, so as a longer duration of 2.550 μs, to prevent the generation of micro-bubbles. A dampening segment was applied to phase four to prevent the nozzles from sucking air back in and get prepared for the next ejection. A video of the nozzles' jetting with the optimum jetting waveform, meniscus vacuum value (3.5 H₂O) and jetting voltage peak (˜24.30 V) was take, showing a well alignment, stable jetting (please refer to the support information). No clog or misdirected jetting occurred during continuous working for 1 hour, revealing a robust and high-resolution printing with ammonium tetrachloropalladate (II) solution was achieved.

### Examples 5

ELD of copper and thermal sintering. ELD process was conducted to apply copper pattern onto the printed feature. The detailed process of ELD can be found in former literatures. Briefly, patterns printed with inks featuring Pd salt concentration of 10 mM, 20 mM, 30 mM, 35 mM, 40 mM, 45 mM, 50 mM, 55 mM and 60 mM were put into a plating bath containing 1:1 mixture of freshly prepared solutions I and II. Solution I consists of 13 g/L CuSO₄.5H₂O, 12 g/L NaOH and 29 g/L KNaC₄H₄O₅.4H₂O which were added into distilled water in sequence. Solution II is 9.5 mL/L HCHO in distilled water. Deposition time was controlled to 30 min, 40 min, 60 min, 120 min, and 180 min for printed patterns under the same setting. Deposited copper lines were air dried and then put into a Fisher 1500 DEG Tube Furnace for sintering. Nitrogen was flowing for 30 minutes before heating to ensure that no residual oxygen was in that tube. Sintering was kept for an hour under continuous nitrogen flow at 200° C. and heating rate set to 15° C./min.

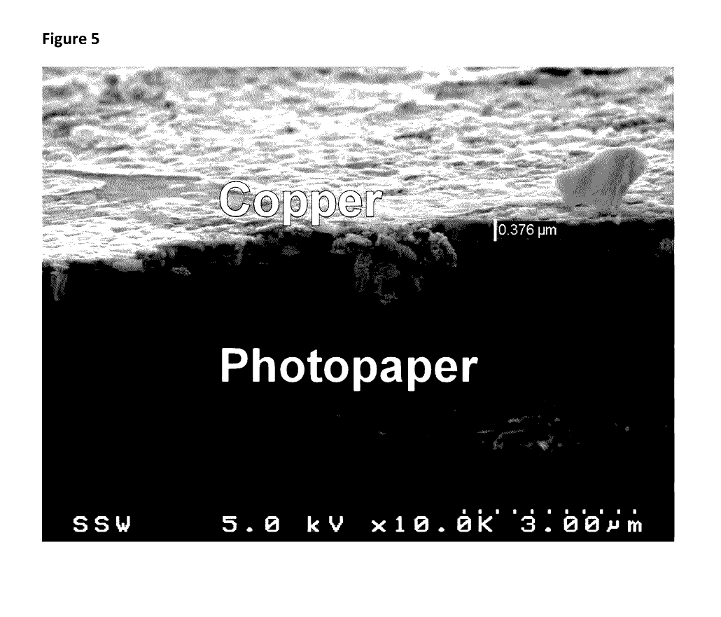

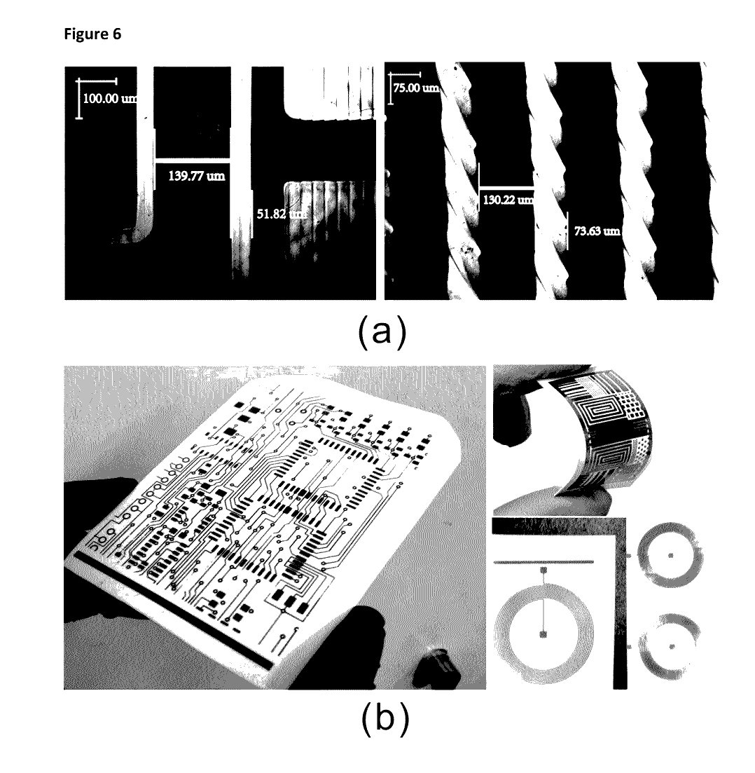

ELD of copper was conducted under ambient environment, showing a satisfied deposition rate. Patterns were taken out of the deposition solution when no observable changes happened to their surfaces. Deposition time is 3˜4 times longer than conventional ELD which happens on a PET or PI substrate. Palladium ions first initiate the copper reduction, the reduced copper then serves as catalysts to keep the reaction going. The deposition rate needs to be kept in a certain level so that the freshly reduced copper can maintain its activity and continue its serving as catalyst. A slow deposition rate caused by the ink of low concentration leads to loss of the activity of the reduced copper. Serious dispersion was observed when the ink concentration was above 50 mM since the limited number of quaternary amine on the photopaper couldn't form chemical bonds with the excessive amount of palladium salt. The unbonded palladium salt will then disperse in the photopaper and dissolve in the deposition solution, causing serious loss of resolution. The optimum concentration range was found to be around 40-45 mM and the dimension of the resulted copper patterns printed in this concentration were measured by an opticalmicroscope, showing a slight increment in its width and length (˜0.15 mm, ˜4.5%) due to ink dispersion along the photopaper fibers. The ink with a concentration of 45 mM palladium salt was then adopted for the following complex and functional patterns printing. For the patterns printed with a 45 mM concentration of palladium salt on the photopaper, the copper will stop growing when its thickness reaches ˜350 nm (FIG. 5). We adopted the present method for manufacturing flexible integrated circuits (FIG. 6). A 3M # 600 tape was adopted to test the adhesion, no peeling off was observed after 3 times tearing down, indicating a very strong adhesion between the copper and the photopaper/PET/PI substrate. The tape test showed almost no influence on the conductivity (decrement rate less than 1%) of patterns before/after sintering.

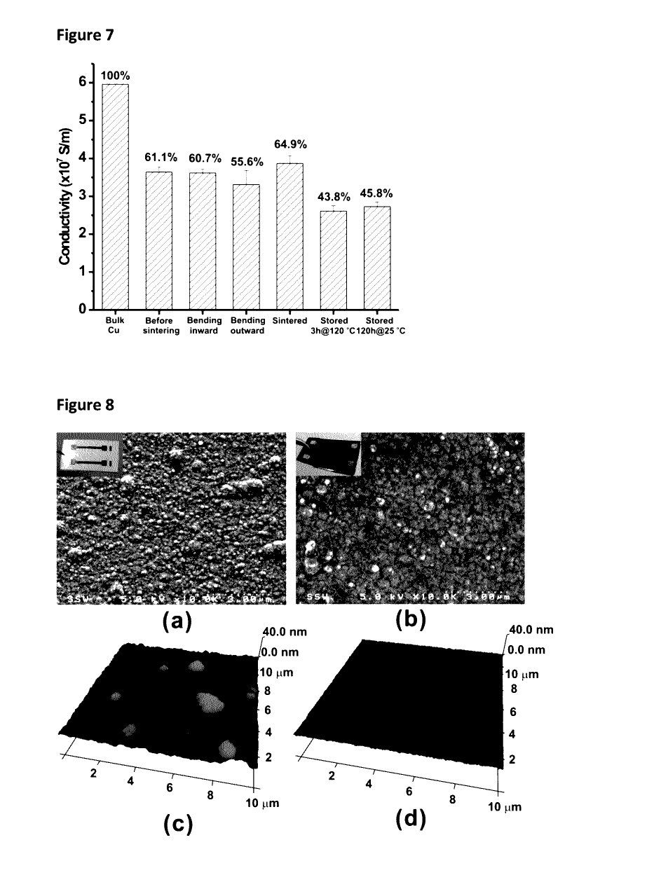

Generally, a sintering process is needed for patterns fabricated by directly ink jetting metal particles on substrates, to render the pattern and make it conductive. While the patterns fabricated using our method have already showed a very good conductivity even before the sintering process, which means sintering is not absolutely necessary. But it was found that sintering can further improve conductivity of metal patterns. The conductivity was measured using a four-probe method, as shown in FIG. 7. The copper lines have already shown good conductivity up to 3.6×10⁷ S/m before sintering. The high conductivity achieved here can be attributed to the abundant metal ions in the ELD copper plating bath, resulting in dense uniform copper layer with good conductivity. For the pattern after taking one hour thermal sintering under nitrogen flow, no copper particles can be observed anymore, leading to an slightly increment (about 4%, FIG. 8) in the conductivity. We also tested the conductivity of the patterns under deformation, results showed that the inward bending has little impact on the conductivity while an outward bending can lead to a ˜6% decrement on its conductivity, caused by some tiny cracking on the surface. The decrement is reversible, when the patterns restore to its original shape, the conductivity will then increase to ˜95% of its initial value. To test the stability of the deposited copper, we put the sample on a hot plate heating up to 120° C. in air for 12 hours, and measured its conductivity every 20 mins. 3 hours later the conductivity tended to be stable and kept its level (˜43.8%) for the rest of the time. We also measured several samples stored under room temperature for more than 180 days and results showed a ˜10% decrement in its conductivity, almost the same as the stable state of samples under 120° C. So the conductivity of copper pattern fabricated in this way will remain the same after a ˜10% rapid decrement.

Roughness was measured using the AFM, the roughness (Ra) of un-sintered copper pattern is ˜50 nm while for the patterns after sintering, and the roughness reduces to 1-2 nm, which gives an explanation to the increased conductivity (FIG. 8). Finally the copper patterns achieve a high conductivity up to 3.87×10⁷ S/m (65.1% of bulk copper), compared to conductivity data of inkjet-printed copper reported in literature, which typically ranges from 10% to 31% of bulk copper. Compared with those copper patterns deposited on plastic substrate (PET/PI) using ELD whose conductivity can reach up to ˜90% bulk, the 65.1% bulk conductivity is not that impressive and the barrier for higher conductivity may be due to the photopaper substrate.

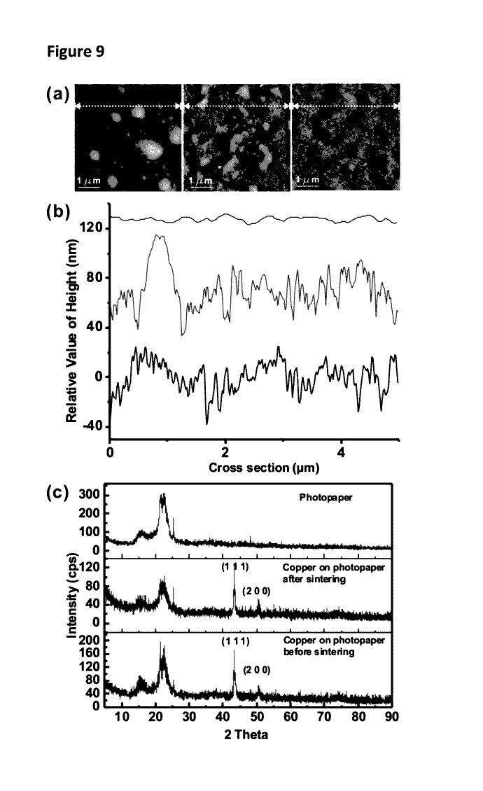

AFM profile scanning patterns of the copper on photopaper, photopaper before and after ELD bath are shown in FIG. 9, many raised areas can be observed in the picture of photopaper after ELD, these raised parts were caused by ELD bath. During the ELD process, the air in between the fibers of the photopaper resulted in these raised areas and thus limited the conductivity of the patterns. We have to say that thermal sintering doesn't suit for the paper-based electronics, even though it does enhance the patterns' conductivity. X-ray diffraction was conducted to study the crystalline structures of the samples (under 40 kV/40 mA, X-Ray, continuous scanning mode, 2 deg./min. scan speed, 0.02 deg. step width, 5-90 deg. scan range, fixed monochord.) FIG. 9(c) shows the XRD patterns of copper patterns deposited on photopaper. Both the samples before and after sintering shows two characteristic peaks for metallic copper crystalline at 43° and 51° presenting for the Bragg's reflection indices of (111) and (200) planes in FCC structure.

### Examples 6

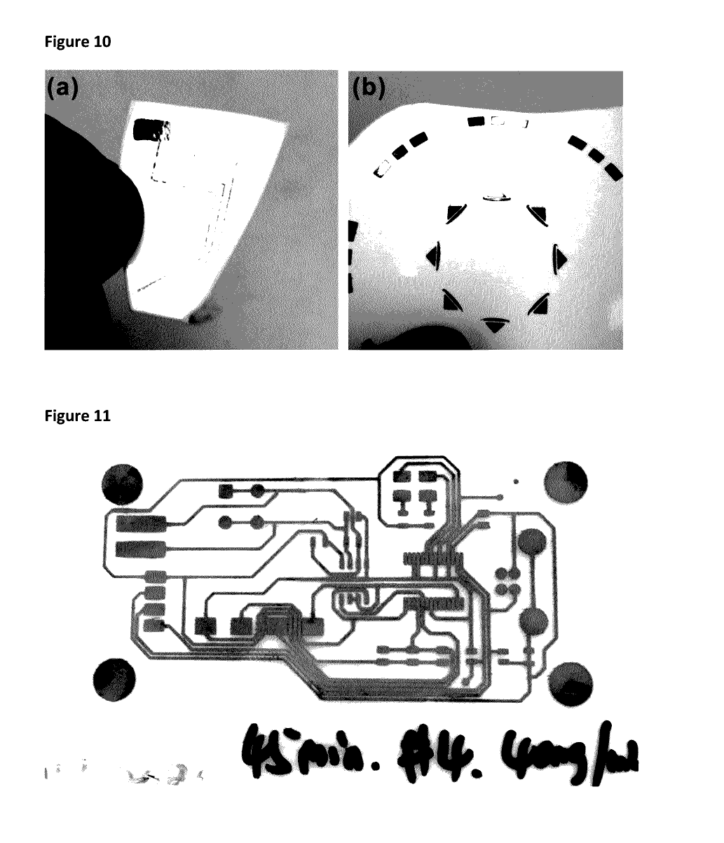

The same ink as is prepared in Example 3 was used to screen printing a pattern, followed by the same ELD process demonstrated in Example 4 for 45 mins. FIG. 10 shows the resulted conductive copper pattern.

### Examples 7

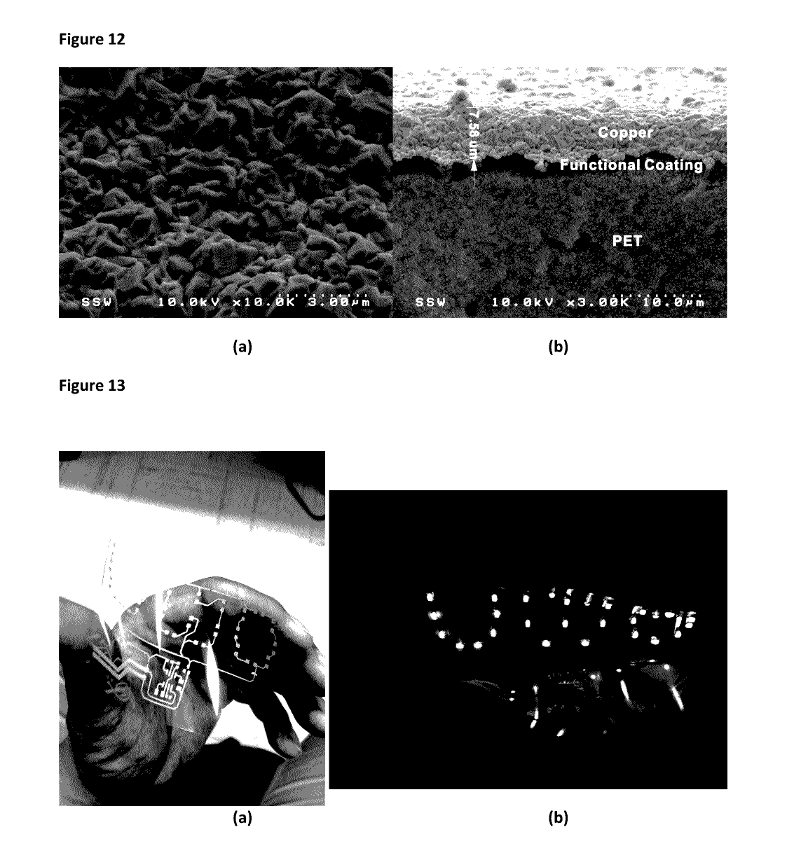

Silver nitrate ink (1% wt %) was printed onto treated PET and was put into ELD for 7 hours for thick copper deposition. The resulted functional pattern was shown in FIG. 11. FIG. 12a shows the surface morphology of the deposited copper, where copper crystal structure was clear to be observed which means that the deposited copper is in high quality and the property of the deposited copper is very close to bulk copper. FIG. 12b shows the cross section of the deposited copper pattern fabricated used the above method, a thick copper layer with a thickness about 7.5 microns can be observed, illustrating extreme good conductivity of this pattern.

### Examples 8

1 g (NH₄)₂PdCl₄ was mixed with Xerox phaser 3300 toner, and was used to printed onto regular untreated substrate. The printed pattern was then immersed in the solution for 2 h for copper plating. FIG. 13a shows the deposited functional pattern after 2 h ELD and FIG. 13b shows the flexible circuit working under bending.

### Examples 9

To demonstrate the fabrication ability of this new developed solvent free method for printed electronics, we produced a double layer flexible LED display.
[1] Lupo D, Clemens W, Breitung S, Hecker K. OE-A Roadmap for Organic and Printed Electronics. In: Cantatore E, editor. Applications of Organic and Printed Electronics: Springer US; 2013. p. 1-26.
[2] Secor E B, Lim S, Zhang H, Frisbie C D, Francis L F, Hersam M C. Gravure Printing of Graphene for Large-area Flexible Electronics. Adv Mater. 2014.
[3] Lessing J, Glavan A C, Walker S B, Keplinger C, Lewis J A, Whitesides G M. Inkjet Printing of Conductive Inks with High Lateral Resolution on Omniphobic “R Paper” for Paper-Based Electronics and MEMS. Adv Mater. 2014.
[4] Hong S, Yeo J, Kim G, Kim D, Lee H, Kwon J, et al. Nonvacuum, Maskless Fabrication of a Flexible Metal Grid Transparent Conductor by Low-Temperature Selective Laser Sintering of Nanoparticle Ink. Acs Nano. 2013; 7:5024-31.
[5] Perelaer J, Abbel R, Wunscher S, Jani R, van Lammeren T, Schubert U S. Roll-to-Roll Compatible Sintering of Inkjet Printed Features by Photonic and Microwave Exposure: From Non-Conductive Ink to 40% Bulk Silver Conductivity in Less Than 15 Seconds. Advanced Materials. 2012; 24:2620-5.
[6] Wang X L, Hu H, Shen Y D, Zhou X C, Zheng Z J. Stretchable Conductors with Ultrahigh Tensile Strain and Stable Metallic Conductance Enabled by Prestrained Polyelectrolyte Nanoplatforms. Advanced Materials. 2011; 23:3090-+.
[7] Rogers J A. ELECTRONICS A diverse printed future. Nature. 2010; 468:177-8.
[8] Ahn B Y, Duoss E B, Motala M J, Guo X Y, Park S I, Xiong Y J, et al. Omnidirectional Printing of Flexible, Stretchable, and Spanning Silver Microelectrodes. Science. 2009; 323:1590-3.

### A Printing Method for Fabrication of Printed Electronics

### Background

Printed flexible electronics and devices which can maintain functionality when subject to a large deformation and stress have broad applications. The conductivity, the resolution and the cost are of great concerns for manufacturing. There is an increasing demand for high quality and low cost electronic components such as RFID tags, super capacitor, flexible sensor and devices, which require innovative fabrication techniques that are faster but cheaper compared to traditional production methods. It is predicted that the market of flexible organic and printed electronics will exceed $300 billion by 2028.[1] Conventional fabrication methods for electronics are mostly based on lithography technique, a complex and time-consuming process that involves expensive facilities and large volumes of hazardous waste. The emerging nanotechnology is also evolved in fabricating electronics such as solar cell and super capacitor, however, its high cast and requirement for high-end facilities limit its appeal. In this regard, printing techniques, such as inkjet printing, flexographic printing, laser printing, and screen printing, and coating techniques, such as spray coating and non-vacuum deposition, have emerged as promising technical trends to produce flexible electronics and devices.[2-8]

WO2011019523 A3 disclosed a method based on roll mechanics and conductive inks for making printed electronics, WO2014021941 A1 and US20030151028 A1 disclosed a method of synthesizing conductive inks and demonstrated the fabrication of printed electronics using the flexographic and gravure techniques. In U.S. Pat. No. 8,697,485 B2, a conductive graphene ink was printed electrohydrodynarnically onto glass substrate based on the method disclosed in WO 2007/053621. The mask based screen printing technique was also adopted to print functional multilayer structure, and was demonstrated in U.S. Pat. No. 6,573,023 B2. Inkjet printing, which is widely used in home and office, has also been employed extensively as a low cost tool to explore various aspects of printed electronics in a laboratory setting, such as ITO free polymer solar cell, functional polymer films, complex heterogeneous tissue constructs and thin film transistors. For printed electronics, most of the research efforts are focused on direct printing of metal nanoparticles or conductive polymer, followed by thermal or other treatment to make them conductive. For example, as is disclosed in U.S. Pat. No. 8,810,996 B2, graphene oxide conductive ink was deposited onto the substrate using inkjet method, and in US20140302292 A1 nanoparticles were deposited by inkjet printing to form functional devices. Although the resolution of the final resulted metal pattern has been improved, clogging is always a common critical issue for micron size nozzles due to the accumulation of nanoparticles at the nozzle opening. In addition, other than the high cost of Ag-nanoparticles, more critical issues reside in the oxidization and sedimentation stability of the corresponding inks, which generally requires a large amount of stabling and decoration agent and a very low concentration of metal particles. All of these will consequently lead to a high resistance of the printed patterns. Thus it is desirable to find an efficient and low cost way to obtain high quality electronic circuits, especially with thick metal to achieve high conductivity.

### SUMMARY

In one aspect, this invention develops a new concept of making high quality printed electronics. Instead of printing conductive inks, the catalyst based ink was printed followed by electroless deposition (ELD) to enable electronic circuits with thick metal on various substrates. The method comprises:
(i) modifying substrates with functional groups for catalyst capturing and immobilization;
(ii) printing catalyst based inks on desired substrates, such as paper, plastic, aluminum oxide, glass, silicon, metals and textiles;
(iii) electroless deposition of metals to make sufficiently thick metal layer; and
(iv) post-printing treatment like thermal sintering, inductive sintering or photonic sintering.

The modification of step (i) is carried out by surface initiated polymerization of acrylate or methacrylate monomer, or self-assembly of polyelectrolytes to introduce functional groups for catalyst immobilization during printing. A post-application process like cross-linking or curing may be applied to improve the adhesion.

In another aspect, this invention develops catalyst based inks for printing electronics circuit on various substrates. The catalyst based ink may be in the form of liquid, gel, aerosol, paste, solid or powder. The formed catalyst based ink can be applied on substrate by both printing techniques, including inkjet printing, screen printing, laser printing, gravure printing and flexographic printing, and other deposition methods, including spray coating, non-vacuum deposition, micro-contact printing and etc. The catalyst based ink can be formed with various noble metals, such as Pd, Pt, Au or Ag, by either dissolving in a liquid solvent like a mixture of water and glycerol to form solution or gel with appropriate viscosity and surface tension, or mixing with a solid solvent like toner to formulate a powder form of ink. Overall, the catalyst based ink can be prepared in different forms to be suitable for various applications with the choice of the substrate and the printing technique.

In another aspect, this invention provides a solvent-free approach to fabricate high quality flexible electronics by printing a modified toner. Only two steps are involved in the procedure: printing designed pattern with solid catalyst based ink and ELD of copper. The key to this solvent free printing method is the fabrication of a functional toner additive which is compatible with the regular laser printer, does not affect the electric charge properties of the original toner, has a strong adhesion with the printed toner, and does not dissolve or migrate away from the printed pattern during the ELD process.

In yet another aspect, this invention provides an ELD method to fabricate electronics circuit with a thick layer of metal. The method includes the steps of: (a) printing desired features on a substrate with prepared catalyst; (b) conducting ELD process to plate desired metal with sufficient thickness on the printed feature; and (c) post-printing treatment to improve the quality of obtained circuit. The printing can be performed with desktop inkjet printer, commercial material printer, laser printer or other printing/deposition methods mentioned. Particularly, for inkjet printing, pure catalyst noble-metal-containing salt solution without using any kind of particles can overcome the issue of nozzle blocking and enables greater printing resolution. And for solvent free laser printing, noble-metal-containing salt was mixed with thermoplastic polymer enabling functional high resolution laser printing, and making high performance thick copper feature to realize high quality electronics circuit.

The ELD is conducted by immersing into a plating bath for 1-120 min, wherein the plating bath can be Cu plating, Ni plating and Silver plating. The Cu plating bath contains a 1:1 mixture of freshly prepared solutions A and B. Solution A contains 12 g/L NaOH, 13 g/L CuSO₄.5H₂O and 29 g/L potassium sodium tartrate and Solution B contains 9.5 mL/L HCHO in water. The Ni plating bath contains 40 g/L Ni₂SO₄.5H₂O, 20 g/L sodium citrate, 10 g/L lactic acid, and 1 g/L dimethylamine borane (DMAB) in water. A nickel stock solution of all components except the DMAB was prepared in advance. A DMAB aqueous solution was prepared separately. The stock solutions were prepared for a 4:1 volumetric proportion of nickel-to-reductant stocks in the final electroless bath. The silver plating bath contains 1:1 mixture of freshly prepared 5 g/L of potassium sodium tartrate solution and solution containing 1 g/L AgNO₃ and a small amount of ammonia water.

The post-printing treatment mainly comprises a sintering process to improve conductivity of the metal patterns by ELD and lamination process. Thermal sintering, inductive sintering or photonic sintering by high-power pulsed light may be used for the sintering purpose.

Additional aspects of the invention will be set forth further in the following context, including figures, the detailed description, and any claims, or can be learned by practice of the invention. It is to be understood that both the foregoing general description and the following detailed description are exemplary and explanatory only and are not restrictive of the invention as disclosed.

### BRIEF DESCRIPTION OF THE DRAWINGS

FIG. 1 is a schematic illustration of paper-based metal patterns with high resolution and conductivity via printing catalyst based ink and subsequent ELD process.

FIG. 2 (a) shows UV/visible-spectra (fitted) of freshly prepared palladium (II) salt ink (triangle facing down) and inks after storage at room temperature for 8 hours (triangle facing up), 3 days (round circle), 180 days (square) and 180 days stored under 4° C. (diamond), and images of prepared inks from one day to 180 days; (b) catalyst based ink prepared with toner.

FIG. 3 shows: (a) Misdirected jetting caused by accumulated leaked ink around the nozzle. (b) Satellite droplets caused by relative high jetting voltage. (c) Droplets after applying the optimum parameters (meniscus vacuum: 3.5 H₂O, jetting voltage peak ˜24.30 V, single jetting duration: 32.192 μs (phase 1: 9.792 μs, phase 2: 6.160 μs, phase 3: 8.496 μs, phase 4: 5.184 μs), maximum jetting frequency: 20 kHz).

FIG. 4 shows Modified waveform for the ammonium etrachioropalladate (II) ink.

FIG. 5 shows scanning electron microscopy (SEM) image of the cross section of the ELD copper layer.

FIG. 6 shows: (a) Microscope images of the final copper patterns of high resolution (left) and inductive micro-coil (right); (b) Flexible Functional circuit board (left), integrated circuits with RFID antenna (right).

FIG. 7 is the conductivity comparison of sintered, un-sintered, bent (inward and outward, radius of curvature: 1 cm⁻¹), un-bent, stored 3 hours under 120° C., stored 180 days under room temperature and bulk copper lines.

FIG. 8 shows: (a) SEM images of the deposited copper before sintering and (b) after one hour thermal sintering under nitrogen flow; (c) atomic force microscopy (AFM) 3D morphology of copper layer before sintering and (d) after one hour thermal sintering.

FIG. 9 (a) AFM images showing the roughness of copper (before sintering) on photopaper after ELD bath and photopaper before ELD; (b) AFM Section profiles of selected parts showing in (a) with white dash lines, corresponding to the copper, photopaper after ELD and photopaper before ELD respectively. (c) XRD patterns of photopaper, copper on photopaper after sintering and copper on photopaper before sintering.

FIG. 10 Electronics pattern prepared by screen printing method

FIG. 11 Electronics circuit prepared with silver nitrite as catalyst by inkjet printing

FIG. 12 (a) SEM image of the copper surface prepared by laser printing; (b) a typical cross section of thick copper on the treated substrate

FIG. 13 (a) Electronics circuit prepared by laser printing method and (b) a functional circuit with LED flashing controlled by electronic components

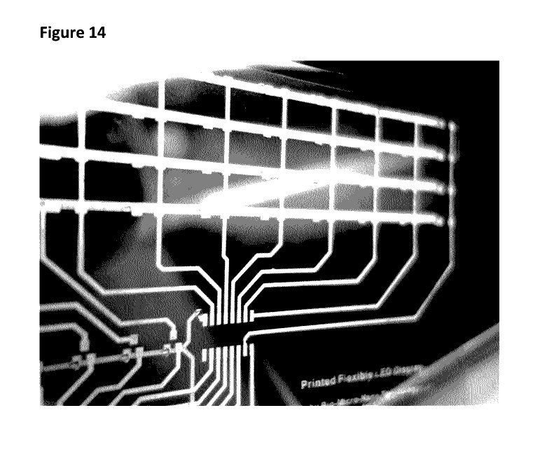

FIG. 14 Double layer flexible LED display prepared by laser printing catalyst based ink

### DETAILED DESCRIPTION

As used herein, the “catalyst ink” encompasses materials that may include noble metal salts, solvent and polymers. Examples of polymers include polyesters, polyimides, polyamide, ABS, polylactide (PLA) etc. The catalyst ink may be in the form of liquid, gel, aerosol, paste, solid or powder. The catalyst ink may be applied to the substrate using any suitable coating or printing technique. The candidate coating or printing techniques include, but not limited to, spray coating, spin coating, inkjet printing, screen printing, laser printing, flexographic printing, microcontact printing, xerography etc. The substrate may be any suitable materials such as paper, polymers, glass, silicon, metals, wood, and textile, and so on.

In this invention, a convenient and low-cost method for printed electronics has been developed that involves a process of printing catalysts and a following ELD process, and post-printing treatment to prepare high-resolution and high-conductivity metal patterns. ELD is an auto-catalytic technique used to deposit metals (copper, nickle, etc.) on various substrates such as paper, plastic, aluminum oxide, glass, silicon, metals and textiles. The mechanism of ELD has been well studied these years, making it a convincing technique for making metal coating and patterns. Abundant metal ions in the ELD bath can create patterns with dense surface, which in turn results in good conductivity close to bulk materials.

For example, as shown in the scheme of FIG. 1, metal patterns were fabricated on flexible substrates by inkjet printing.

The substrates used for printing were first modified by polyelectrolyte by surface initiated atom transfer radical polymerization.

A glycerol-water solution with viscosity of ˜11 centipoise (cp) was achieved by mixing anhydrous glycerol and distilled water in the ratio 3:2 by volume. Noble metal salt was dissolved in the mixture to form a solution with viscosity of 10-12 cp at room temperature. The noble metal solution was then ink jet printed on the polyelectrolyte modified substrate.

Electroless deposition process was conducted to apply copper pattern onto the printed feature by immersing into the freshly prepared plating bath for different time to achieve desired thickness, particularly, large thickness of metal layer can be obtained using this method.

### EXAMPLES

The invention can be further understood by the skilled person with reference to the following examples, which are exemplary, and the inventors' technology is not limited in scope by the exemplified embodiments. Various modifications of the present technology in addition to those described herein will become apparent to those skilled In the art from this description and accompanying figures.

### Examples 1

Modification of substrate. EPSON Ultra Premium Photopaper Glossy, treated with polyelectrolytes containing quaternary ammonium was selected to be substrate.

### Examples 2

Preparation of noble metal salt ink. A glycerol-water solution with viscosity of ˜11 centipoise (cp) was achieved by mixing anhydrous glycerol and distilled water in the ratio 3:2 by volume. Ammonium tetrachloropalladate (II) was then added, followed by 4 minutes mixing In the mixer until a clear dark yellow solution was obtained. The optimum viscosity for inkjetable fluids in piezoelectric Drop-on-Demand (DOD) printhead reported in literature is 10-12 cp at room temperature. Based on these, inkjet printable inks containing different concentration of palladium ions were prepared and viscosity was measured. To find the optimum ink for the following inkjet printing and ELD process, solutions with different Pd salt concentration (10-60 mM) were prepared in the same way. All prepared inks were degassed under a vacuum chamber of 2 psi for 1 hour to remove dissolved gas, followed by filtering with a 0.2 μm springe filter to get rid of undesired particles which could cause jetting clog. The final viscosity was measured with a Gilmont GV-2100 Falling Ball Viscometer to further confirm it was in a proper range.

Negatively charged tetrachloropalladate group (−PdCl₄²⁻) tends to form chemical bonds with the positively charged quaternary amine group (NR₄⁺—) on the photopaper. A bivalent tetrachloropalladate group will combine with two monovalent quaternary amine groups when the ink droplet is in contact with the photopaper substrate which results in a strong adhesion between the palladium ions and the substrate. Rate of ELD of copper as well as the plated copper density are proportional to the concentration of catalyst (palladium Ion in this case), thus a high concentration of the palladium salt is preferred. However, the number of quaternary amine groups on the surface of photopaper is limited, which means excessive palladium salt will result in unbonded palladium ions on the surface. Unbonded ions will disperse on the photopaper and dissolve in deposition solution during the process of ELD, causing serious losses in resolution. Therefore, inks with concentrations ranging from 10 mM to 60 mM were prepared to find the optimal solution. For inks stored at room temperature, visible precipitation was clearly observed 3 days later and gradually increased with time, as shown in FIG. 2. The palladium salt solutions after standing up to 180 days at 4° C. showed no precipitation or deterioration. The color of the ink is still dark yellow just as that of the initial solution. The ink remained stable under 4° C. for more than 180 days without observation of sediment and also showed its capability of producing successful printing results. Inks stored under room temperature after 30 days still showed its ability to trigger the ELD process, but the ELD process was in a very low rate, usually taking more than 3 hours to complete and the deposited patterns were no longer uniform and continuous, indicating that such inks were no longer suitable for making a high resolution functional circuits. Thus, all the inks used for final printing were either fresh made or those stored at 4° C.

### Example 3

The preparation of catalyst-containing toner (case of solid ink): As-synthesized toner and commercial laser printing toners are both available for the production of modified toner.

The catalyst ammonium tetrachloropalladate(II) [(NH4)2PdCl4] is grinded into fine powders by ball milling or other pulverization method, such as planetary ball milling, mechanical grinding. Then the grinded catalyst powders are dry blended with toner particles by mechanical method, typically including ball milling, blast mixing, and stirring mixing. Small, homogeneous, and evenly colored catalyst-containing toner is produced and collected for the characterization and use.

### Examples 4

Inkjet printing and parameters optimization. Printing patterns were designed and drew with vector drawing software with color values set to R=0, G=0, B=0 and exported as binary bmp format in bitmap color model with a resolution of 1300 ppi. Inkjet printing was performed using a commercially available inkjet Dimatix DMP-2800 materials printer (FUJIFIL Dimatix, USA), equipped with a 1 pL piezoelectric DOD 16-jet cartridge that can deposit features as small as 20 μm. Printing parameters such as jetting period, jetting voltage control waveform, meniscus vacuum, printhead temperature were dynamically adjusted according to the real-time droplets video generated by a built-in high frequency camera. Epson Ultra-Premium Glossy photopaper was used as the substrate for printing and was cut into a 10 cm×10 cm square to reduce deformation caused by heating and wetting. Prepared photopaper was placed on a vac-sorb substrate with temperature at 30° C. and fixed by scotch tape. Lines of the same width were printed with the drop space set to 20 μm, 25 μm, 30 μm and 35 μm respectively and examined by microscope. Results showed a drop space of 25 μm giving the best pattern thus complex and functional patterns were then printed with optimum settings (maximum jetting frequency 20 kHz, drop space 25 μm, meniscus vacuum 3.5 H₂O, printhead temperature 30° C., printhead angle 3.6°, jetting period 41.792 μs, jetting voltage 23.60±0.4 V, printing height 150 μm, cleaning cycle of 1 s purging—1 s spitting—2 s blotting, tickle mode on with frequency 2 kHz).

The cartridge of ink jetting devices is always operated under negative pressure to keep the meniscus at the edge of the nozzle and prevent the ink from dripping under the action of gravity. The pressure difference between the inside and outside of the cartridge, which is also known as the meniscus vacuum, needs to be adjusted depending on the viscosity and surface tension of the ink. To obtain the optimum meniscus vacuum level, a built-in camera was used to monitor the formation of droplets in real time. Meniscus vacuum level was set to 3.2, 3.3, 3.5, 3.8 and 4.0 (inches of water) and under each level the printhead continuously worked for 10 minutes. Results showed that a meniscus vacuum of 3.5 H₂O gave the most stable and reliable ejected droplets. Leakage was observed on some of the nozzles when the vacuum level was lower than 3.5 H₂O. The leaked ink attached and accumulated around the nozzle, causing misdirected jetting and blocked nozzle. For the vacuum level higher than 3.5 H₂O, a relative high voltage (˜28 V) must be applied to the nozzle in order to overcome the excessive negative pressure to make it jet. However, the increased voltage results in the breakup of the liquid ligament which consequently leads to the generation of a primary drop and one or several satellite droplets. Typically, the satellite droplets may cause undesired patterns and a serious loss in resolution, and therefore should be avoided as much as possible. For the piezoelectric printhead, the velocity of droplet ejected from the nozzle is a function of applied voltage. We observed that the distance (from the nozzle plate to the place where droplet fully formed) traveled by the droplet also increased with the applied voltage. Higher voltage results in a bigger dot diameter because of the increased ink droplet's mass and velocity, which means a reduction in the printed resolution. By applying a meniscus vacuum of 3.5 H₂O, the optimum jetting voltage peak for the palladium ink was found to be ˜24.3 V using the same real-time monitoring method.

Nozzle clog was observed sometimes during real-time monitor, which was unacceptable for a high resolution printing (FIG. 3). Since all the inks were degased and filtered by a 0.2 μm syringe filter, clogging should not be caused by undesired large particles or bubbles in the ink. Thus, the great possibility may reside in the voltage waveform used for controlling the bimorph on each nozzle. The bimorph is slightly deflected so that the fluid chamber above the nozzle is depressed by a bias voltage. Typically, the voltage waveform is divided into four segments, and each segment has three properties: slew rate, duration and level. The first segment is called the loading work during which a decreased voltage is applied to the bimorph at the beginning of the jetting, bringing the bimorph back to a relaxed position with the chamber at its maximum volume. However, for the palladium salt ink the loading work segment will lead to the generation of micro-bubbles in the nozzle, prohibiting formation of droplets since the nozzle works in a high jetting frequency up to 20 kHz. Effect of such micro-bubbles is magnified in a nozzle with a diameter of only 10 micron. Thus, we reduced the decreased level of the first phase, and got the optimum jetting waveform shown in FIG. 4. A reduced level (˜50% of the initial one) of jetting voltage was applied to phase one, so as a longer duration of 2.550 μs, to prevent the generation of micro-bubbles. A dampening segment was applied to phase four to prevent the nozzles from sucking air back in and get prepared for the next ejection. A video of the nozzles' jetting with the optimum jetting waveform, meniscus vacuum value (3.5 H₂O) and jetting voltage peak (˜24.30 V) was take, showing a well alignment, stable jetting (please refer to the support information). No clog or misdirected jetting occurred during continuous working for 1 hour, revealing irobust and high-resolution printing with ammonium tetrachloropalladate (II) solution was achieved.

### Examples 5

ELD of copper and thermal sintering. ELD process was conducted to apply copper pattern onto the printed feature. The detailed process of ELD can be found in former literatures. Briefly, patterns printed with inks featuring Pd salt concentration of 10 mM, 20 mM, 30 mM, 35 mM, 40 mM, 45 mM, 50 mM, 55 mM and 60 mM were put into a plating bath containing 1:1 mixture of freshly prepared solutions I and II. Solution I consists of 13 g/L CuSO₄.5H₂O, 12 g/L NaOH and 29 g/L KNaC₄H₄O₆.4H₂O which were added into distilled water In sequence. Solution II is 9.5 mL/L HCHO in distilled water. Deposition time was controlled to 30 min, 40 min, 60 min, 120 min, and 180 min for printed patterns under the same setting. Deposited copper lines were air dried and then put into a Fisher 1500 DEG Tube Furnace for sintering. Nitrogen was flowing for 30 minutes before heating to ensure that no residual oxygen was in that tube. Sintering was kept for an hour under continuous nitrogen flow at 200° C. and heating rate set to 15° C./min.

ELD of copper was conducted under ambient environment, showing a satisfied deposition rate. Patterns were taken out of the deposition solution when no observable changes happened to their surfaces. Deposition time is 3˜4 times longer than conventional ELD which happens on a PET or PI substrate. Palladium ions first initiate the copper reduction, the reduced copper then serves as catalysts to keep the reaction going. The deposition rate needs to be kept in a certain level so that the freshly reduced copper can maintain its activity and continue its serving as catalyst. A slow deposition rate caused by the ink of low concentration leads to loss of the activity of the reduced copper. Serious dispersion was observed when the ink concentration was above 50 mM since the limited number of quaternary amine on the photopaper couldn't form chemical bonds with the excessive amount of palladium salt. The unbonded palladium salt will then disperse in the photopaper and dissolve in the deposition solution, causing serious loss of resolution. The optimum concentration range was found to be around 40-45 mM and the dimension of the resulted copper patterns printed in this concentration were measured by an optical microscope, showing a slight increment in its width and length (˜0.15 mm, ˜4.5%) due to ink dispersion along the photopaper fibers. The ink with a concentration of 45 mM palladium salt was then adopted for the following complex and functional patterns printing. For the patterns printed with a 45 mM concentration of palladium salt on the photopaper, the copper will stop growing when its thickness reaches ˜350 nm (FIG. 5). We adopted the present method for manufacturing flexible integrated circuits (FIG. 6). A 3M #600 tape was adopted to test the adhesion, no peeling off was observed after 3 times tearing down, indicating a very strong adhesion between the copper and the photopaper/PET/PI substrate. The tape test showed almost no influence on the conductivity (decrement rate less than 1%) of patterns before/after sintering.

Generally, a sintering process is needed for patterns fabricated by directly ink jetting metal particles on substrates, to render the pattern and make it conductive. While the patterns fabricated using our method have already showed a very good conductivity even before the sintering process, which means sintering is not absolutely necessary. But it was found that sintering can further improve conductivity of metal patterns. The conductivity was measured using a four-probe method, as shown in FIG. 7. The copper lines have already shown good conductivity up to 3.6×10⁷ S/m before sintering. The high conductivity achieved here can be attributed to the abundant metal ions in the ELD copper plating bath, resulting in dense uniform copper layer with good conductivity. For the pattern after taking one hour thermal sintering under nitrogen flow, no copper particles can be observed anymore, leading to an slightly increment (about 4%, FIG. 8) in the conductivity. We also tested the conductivity of the patterns under deformation, results showed that the inward bending has little impact on the conductivity while an outward bending can lead to a ˜6% decrement on its conductivity, caused by some tiny cracking on the surface. The decrement is reversible, when the patterns restore to its original shape, the conductivity will then increase to ˜95% of its initial value. To test the stability of the deposited copper, we put the sample on a hot plate heating up to 120° C. in air for 12 hours, and measured its conductivity every 20 mins. 3 hours later the conductivity tended to be stable and kept its level (˜43.8%) for the rest of the time. We also measured several samples stored under room temperature for more than 180 days and results showed a ˜10% decrement in its conductivity, almost the same as the stable state of samples under 120° C. So the conductivity of copper pattern fabricated in this way will remain the same after a ˜10% rapid decrement.

Roughness was measured using the AFM, the roughness (Ra) of un-sintered copper pattern is ˜50 nm while for the patterns after sintering, and the roughness reduces to 1-2 nm, which gives an explanation to the increased conductivity (FIG. 8). Finally the copper patterns achieve a high conductivity up to 3.87×10⁷ S/m (65.1% of bulk copper), compared to conductivity data of inkjet-printed copper reported in literature, which typically ranges from 10% to 31% of bulk copper. Compared with those copper patterns deposited on plastic substrate (PET/PI) using ELD whose conductivity can reach up to ˜90% bulk, the 65.1% bulk conductivity is not that impressive and the barrier for higher conductivity may be due to the photopaper substrate.

AFM profile scanning patterns of the copper on photopaper, photopaper before and after ELD bath are shown in FIG. 9, many raised areas can be observed in the picture of photopaper after ELD, these raised parts were caused by ELD bath. During the ELD process, the air in between the fibers of the photopaper resulted in these raised areas and thus limited the conductivity of the patterns. We have to say that thermal sintering doesn't suit for the paper-based electronics, even though it does enhance the patterns' conductivity. X-ray diffraction was conducted to study the crystalline structures of the samples (under 40 kV/40 mA, X-Ray, continuous scanning mode, 2 deg./min. scan speed, 0.02 deg. step width, 5-90 deg. scan range, fixed monochord.) FIG. 9(c) shows the XRD patterns of copper patterns deposited on photopaper. Both the samples before and after sintering shows two characteristic peaks for metallic copper crystalline at 43° and 51° presenting for the Bragg's reflection indices of (111) and (200) planes in FCC structure.

### Examples 6

The same ink as is prepared in Example 3 was used to screen printing a pattern, followed by the same ELD process demonstrated in Example 4 for 45 mins. FIG. 10 shows the resulted conductive copper pattern.

### Examples 7

Silver nitrate ink (1% wt %) was printed onto treated PET and was put into ELD for 7 hours for thick copper deposition. The resulted functional pattern was shown in FIG. 11. FIG. 12a shows the surface morphology of the deposited copper, where copper crystal structure was clear to be observed which means that the deposited copper is in high quality and the property of the deposited copper is very close to bulk copper. FIG. 12b shows the cross section of the deposited copper pattern fabricated used the above method, a thick copper layer with a thickness about 7.5 microns can be observed, illustrating extreme good conductivity of this pattern.

### Examples 8

1 g (NH₄)₂PdCl₄ was mixed with Xerox phaser 3300 toner, and was used to printed onto regular untreated substrate. The printed pattern was then immersed in the solution for 2 h for copper plating. FIG. 13a shows the deposited functional pattern after 2 h ELD and FIG. 13b shows the flexible circuit working under bending.

### Examples 9

To demonstrate the fabrication ability of this new developed solvent free method for printed electronics, we produced a double layer flexible LED display.
[1] Lupo D, Clemens W, Breitung S, Hecker K, OE-A Roadmap for Or anic and Printed Electronics. In: Cantatore E, editor. Applications of Organic and Printed Electronics: Springer US; 2013. p. 1-26.
[2] Secor E B, Lim S, Zhang H, Frisbie C D, Francis L F, Hersam M C. Gravure Printing of Graphene for Large-area Flexible Electronics. Adv Mater. 2014.
[3] Lessing J, Glavan A C, Walker S B, Keplinger C, Lewis J A, Whitesides G M. Inkjet Printing of Conductive Inks with High Lateral Resolution on Omniphobic “R Paper” for Paper-Based Electronics and MEMS. Adv Mater. 2014.
[4] Hong S, Yea J, Kim G, Kim D, Lee H. Kwon J, et al. Nonvacuum, Maskless Fabrication of a Flexible Metal Grid Transparent Conductor by Low-Temperature Selective Laser Sintering of Nanoparticle Ink. Acs Nano. 2013; 7:5024-31.
[5] Perelaer J, Abbel R, Wunscher S, Jani R, van Lammeren T, Schubert U S. Roll-to-Roll Compatible of Inkjet Printed Features by Photonic and Microwave Exposure: From Non-Conductive Ink to 40% Bulk Silver Conductivity in Less Than 15 Seconds. Advanced Materials. 2012; 24:2620-5.
[6] Wang X L, Hu H, Shen Y D, Zhou X C, Zheng Z J. Stretchable Conductors with Ultrahigh Tensile Strain and Stable Metallic Conductance Enabled by Prestrained Polyelectrolye Nanoplatforms. Advanced Materials. 2011; 23:3090-+.
[7] Rogers J A. ELECTRONICS A diverse printed future. Nature. 2010; 468:177-8.
[8] Ahn B Y, Duoss E B, Motala M J, Guo X Y, Park S I, Xiang Y J, et al. Omnidirectional Printing of Flexible, Stretchable, and Spanning Silver Microelectrodes. Science. 2009; 323:1590-3.

1. A method of fabricating electronics on substrates by printing catalyst based ink as seeds for electroless deposition, the method comprising:
I. Modifying substrates with functional groups, like polyelectrolytes, wherein the polyelectrolytes have quaternary ammonium groups;
II. Applying catalyst based ink onto the substrate, e.g., by a printing method;
III. Electroless deposition of metals;
IV. Post-printing treatment like thermal sintering, inductive sintering or sintering by pulsed light

2. The method of claim 1, wherein the substrate can be paper, plastic, aluminum oxide, glass, silicon, metals and textiles.

3. The method of claim 1, wherein the modification of substrates is promoted by surface initiated polymerization and self-assembly.

4. The method of claims 1 and 3, wherein the functional group being grafted on the substrate is used to capture and immobilize catalyst like Pd, Ag, Au and Pt.

5. The method of claims 1 and 4, wherein the catalyst can be obtained from a range of noble metal compound, such as chloropalladate, chloroplatinate, chloroaurate and silver nitrate.

6. The method of claims 1 and 5, wherein the catalyst based ink can be in the form of liquid, gel, aerosol, paste, solid or powder.

7. The method of claims 1 and 5, wherein the liquid ink can be formulated to be compatible with all the existing printing technique, including inkjet printing, screen printing, flexographic printing, laser printing, and gravure printing.

8. The method of claims 1 and 5, wherein the catalyst based ink can be applied on substrate with other printing or deposition methods, including spraying, micro-contact printing, non-vacuum deposition and etc.

9. The method of claims 1 and 5, wherein the catalyst based ink in the form of powder, which is mixed with thermoplastic materials, to realize a solvent free approach to fabricate high quality electronics circuits based on laser printing.

10. The method of claim 1, wherein the electroless deposition is promoted by immersing in plating bath for 1-120 min for thin metal layer, 2 h-24 h for thick metal layer.

11. The method of claims 1 and 3, wherein the polyelectrolyte contains quaternary ammonium groups.

12. The method of claims 1 and 7, wherein the noble metal salts are dissolved in the mixture of water and glycerol to form solution with viscosity in a range of 1-20 cp.

13. The method of claims 1 and 10, wherein the plating bath includes Cu plating bath, Ni plating bath, and Ag plating bath.

14. The method of claims 1, 10 and 13, wherein the Cu plating bath contains a 1:1 mixture of freshly prepared solutions A and B. Solution A contains 12 g/L NaOH, 13 g/L CuSO4.5H2O and 29 g/L potassium sodium tartrate. Solution B contains 9.5 mL/L HCHO in water. The Ni plating bath contains 40 g/L Ni2SO4.5H₂O, 20 g/L sodium citrate, 10 g/L lactic acid, and 1 g/L dimethylamine borane (DMAB) in water. A nickel stock solution of all components except the DMAB was prepared in advance. A DMAB aqueous solution was prepared separately. The stock solutions were prepared for a 4:1 volumetric proportion of nickel-to-reductant stocks in the final electroless bath. The silver plating bath contains 1:1 mixture of freshly prepared 5 g/L of potassium sodium tartrate solution and solution containing 1 g/L AgNO3 and a small amount of ammonia water.

15. The method of claims 1, 10, 13 and 14, wherein the metal patterns are sintered by heating.

16. An object manufactured according the method defined by any one of claims 1 to 9.
